(19) United States
(12) Patent Application Publication
(10) Pub. No.: US 2021/0227656 A1
(43) Pub. Date: Jul. 22, 2021

(54) THIN-FILM TRANSISTOR FOR USE WITH LIGHT-EMITTING APPARATUS AND MANUFACTURING METHOD THEREOF

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN)

(72) Inventors: Qinghe WANG, Beijing (CN); Dongfang WANG, Beijing (CN); Tongshang SU, Beijing (CN); Ning LIU, Beijing (CN); Guangyao LI, Beijing (CN); Yongchao HUANG, Beijing (CN); Yang ZHANG, Beijing (CN); Jiawen SONG, Beijing (CN); Zhiwen LUO, Beijing (CN); Liangchen YAN, Beijing (CN)

(73) Assignees: HEFEI XINSHENG OPTOELECTRONICS TECHNOLOGY CO., LTD., Hefei, Anhui (CN); BOE TECHNOLOGY GROUP CO., LTD., Beijing (CN)

(21) Appl. No.: 16/756,467

(22) PCT Filed: Oct. 21, 2019
(86) PCT No.: PCT/CN2019/112218

§ 371 Date: Apr. 15, 2020

(30) Foreign Application Priority Data
Dec. 13, 2018 (CN) 201811525359.5

(51) Int. Cl. H05B 45/18; H01L 29/786; H01L 31/12; H01L 29/49; H01L 29/423; H01L 27/32

(52) U.S. Cl. CPC H05B 45/18; H01L 29/78648; H01L 27/3262; H01L 29/4908; H01L 29/42384; H01L 31/12

(57) ABSTRACT

A thin-film transistor includes: an active layer having a first side and a second side opposing to the first side; a main gate electrode spaced from the active layer on the first side, and including a conductive material; an auxiliary gate electrode spaced from the active layer on the second side, wherein the auxiliary gate electrode includes a phase change material having a phase change temperature; the auxiliary gate electrode is configured to have a transition between insulating and conductive based on a temperature of the auxiliary gate electrode; and the main gate electrode and the auxiliary gate electrode are electrically coupled to each other when the auxiliary gate electrode is conductive.

### CROSS-REFERENCE TO RELATED APPLICATION

The present application claims priority to Chinese Patent Application No. 201811525359.5 filed on Dec. 13, 2018, the disclosure of which is hereby incorporated by reference in its entirety.

### TECHNICAL FIELD

The present disclosure relates generally to the field of display technologies, and more specifically to a thin-film transistor, a light-emitting apparatus utilizing the thin-film transistor, and a manufacturing method thereof.

### BACKGROUND

Thin-film transistors (TFTs) can be integrated into a variety of microelectronic devices. For example, a thin-film transistor can be configured as a switching component or an amplifier component.

More and more functions are added to electronic devices, and consumers demand thinner and lighter electronic devices. As a result, the number of thin-film transistors integrated in a circuit has been increasing. Further, as the power consumption of the electronic devices becomes higher and higher, which will adversely influence the working life of the electronic devices, it is it becomes inconvenient for users as the need to charge associated electronic devices increases in time and frequency, particularly with the increased use of thin-film transistors.

### SUMMARY

In an aspect, a thin-film transistor is provided, including:

an active layer having a first side and a second side opposing to the first side;

a main gate electrode spaced from the active layer on the first side, and comprising a conductive material;

an auxiliary gate electrode spaced from the active layer on the second side, wherein the auxiliary gate electrode comprises a phase change material having a phase change temperature;

the auxiliary gate electrode is configured to have a transition between insulating and conductive based on a temperature of the auxiliary gate electrode; and

the main gate electrode and the auxiliary gate electrode are electrically coupled to each other when the auxiliary gate electrode is conductive.

In some embodiments:

the auxiliary gate electrode is configured to be insulating when the temperature of the auxiliary gate electrode is lower than the phase change temperature; and

the auxiliary gate electrode is configured to be conductive when the temperature of the auxiliary gate electrode is higher than the phase change temperature.

In some embodiments, the phase change material includes vanadium oxide (VO2).

In some embodiments, the auxiliary gate electrode includes both vanadium oxide and germanium.

In some embodiments, the thin-film transistor further includes:

a gate insulating layer between the main gate electrode and the active layer; and

an insulating buffer layer between the auxiliary gate electrode and the active layer.

In some embodiments:

a portion of the auxiliary gate electrode expands beyond a range of an orthographic projection of the active layer over a layer where the auxiliary gate electrode is located; and

the main gate electrode is connected to the portion of the auxiliary gate electrode that expands beyond the range of the orthographic projection of the active layer through one or more connection vias that pass through the gate insulating layer and the insulating buffer layer.

In another aspect, a light-emitting apparatus is provided, including light-emitting components, and driving circuits that are configured to drive the light-emitting components to emit light, wherein the driving circuits include a plurality of thin-film transistors.

In some embodiments, the light-emitting apparatus includes:

a base substrate; and

one or more driving circuits formed over the base substrate;

wherein the base substrate is divided into a plurality of pixel units arranged in an array, wherein a light-emitting component is provided inside each pixel unit.

In some embodiments, the light-emitting apparatus further includes:

a gate line,

wherein the main gate electrode is directly connected to the gate line.

In some embodiments, the light-emitting apparatus further includes a conductivity detection sub-circuit and a voltage adjustment sub-circuit, the conductivity detection sub-circuit is configured to detect whether the auxiliary gate electrode is conductive, then, generate a trigger signal when the auxiliary gate electrode is conductive.

In some embodiments:

the voltage adjustment sub-circuit is configured to provide a first voltage signal to the gate line if the trigger signal is not received, and to provide a second voltage signal to the gate line when the trigger signal is received; and

an absolute value of the second voltage signal is lower than an absolute value of the first voltage signal.

In some embodiments, the conductivity detection sub-circuit is an electric current acquisition device or a temperature detection device.

In some embodiments, the conductivity detection sub-circuit includes:

a near-infrared light-emitting device; and

a near-infrared light detecting device, wherein

the near-infrared light-emitting device is configured to emit near-infrared light towards the auxiliary gate electrode, and

the near-infrared light detecting device is configured to detect an intensity of near-infrared light reflected by the auxiliary gate electrode, and generate the trigger signal.

In another aspect, a driving method of the light emitting apparatus is provided, the method including:

providing a first voltage signal to the main gate electrode when the temperature of the auxiliary gate electrode is lower than the phase change temperature, or a second voltage signal to the main gate electrode when the temperature of the auxiliary gate electrode is higher than the phase change temperature;

wherein an absolute value of the second voltage is lower than an absolute value of the first voltage.

In some embodiments, the driving method further includes detecting an intensity of near-infrared light reflected by the phase change material to thereby determine whether the phase change occurs.

In some embodiments, the driving method further includes detecting a conductivity of the auxiliary gate electrode to thereby determine whether the phase change occurs.

In some embodiments, the driving method further includes adjusting a voltage applied to the main gate electrode based on whether the phase change occurs.

In some embodiments, the detecting the intensity of near-infrared light reflected by the phrase change material includes detecting with a photoresistor.

In some embodiments, the driving method further includes providing heating or cooling to change the temperature of the auxiliary gate electrode.

In some embodiments, the driving method further includes inducing a phrase transition of the phase change material with heat from the light-emitting apparatus, to thereby cause the thin-film transistors to effectively change from a single-gate thin-film transistor to a dual-gate thin-film transistor, and reduce a driving voltage of the thin-film transistor and a power consumption of the light-emitting apparatus.

In some embodiments, the phase transition occurs while a brightness of the light-emitting apparatus is maintained.

### BRIEF DESCRIPTION OF THE DRAWINGS

To more clearly illustrate some of the embodiments, the following is a brief description of the drawings.

The drawings in the following descriptions are only illustrative of some embodiments. For those of ordinary skill in the art, other drawings of other embodiments can become apparent based on these drawings.

FIG. 1A illustrates a top structural view of a thin-film transistor (TFT) being illustrative of various aspects of the present disclosure;

FIG. 1B illustrates a side cross-sectional view of the thin-film transistor from the line A-A in FIG. 1A, this view being illustrative of various aspects of the present disclosure;

FIG. 1C illustrates a side cross-sectional view of the thin-film transistor from the line B-B in FIG. 1A, this view being illustrative of various aspects of the present disclosure;

FIG. 2 illustrates a side cross-sectional view of a first sequential stage of a manufacturing method of a light-emitting apparatus being illustrative of various aspects of the present disclosure;

FIG. 3 illustrates a side cross-sectional view of a second sequential stage of a manufacturing method of a light-emitting apparatus being illustrative of various aspects of the present disclosure;

FIG. 4 illustrates a side cross-sectional view of a third sequential stage of a manufacturing method of a light-emitting apparatus being illustrative of various aspects of the present disclosure;

FIG. 5 illustrates a side cross-sectional view of a fourth sequential stage of a manufacturing method of a light-emitting apparatus being illustrative of various aspects of the present disclosure;

FIG. 6 illustrates a side cross-sectional view of a fifth sequential stage of a manufacturing method of a light-emitting apparatus being illustrative of various aspects of the present disclosure;

FIG. 7 illustrates a schematic view of a display system having a plurality of light-emitting apparatuses arranged in an array being illustrative of various aspects of the present disclosure;

FIG. 8 illustrates a schematic view of an individual light-emitting apparatus being provided with voltage detection and adjustment means being illustrative of various aspects of the present disclosure;

FIG. 9 illustrates an exemplary graphical representation of a temperature sensitive semi-conductor such as vanadium-oxide and germanium compound;

FIG. 10A illustrate a schematic diagram of a driving mechanism of the thin-film transistor according to some embodiments in a first mode;

FIG. 10B illustrate a schematic diagram of a driving mechanism of the thin-film transistor according to some embodiments in a second mode;

FIG. 11 is a schematic diagram illustrating an energy-saving effect of the thin-film transistor according to some embodiments;

FIG. 12 is a schematic diagram illustrating an energy-saving display light source product employing the thin-film transistor according to some embodiments;

FIG. 13 is a schematic diagram illustrating exemplary circuitry for driving the thin-film transistors in the various modes of FIGS. 10A and 10B;

FIG. 14 is another schematic diagram illustrating exemplary circuitry for driving the thin-film transistors in the various modes of FIGS. 10A and 10B;

FIG. 15A is a diagram illustrating transfer characteristic curves for the single gate and the dual gate TFT;

FIG. 15B is a diagram illustrating the transfer characteristic curves for the single gate and the dual gate when the gate voltage is higher than 0; and

FIG. 16 is a diagram illustrating the drive voltage levels before and the after the phase transition.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. can be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or other structure is referred to as being “on” or extending “onto” another element, it can be directly on or extend directly onto the other element or intervening elements can also be present. In contrast, when an element is referred to as being “directly on” or extending “directly onto” another element, there are no intervening elements present.

Likewise, it will be understood that when an element such as a layer, region, or substrate is referred to as being “over” or extending “over” another element, it can be directly over or extend directly over the other element or intervening elements can also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Relative terms such as “below” or “above” or “upper” or “lower” or “horizontal” or “horizontal” can be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Various embodiments of the present disclosure provide a thin-film transistor (TFT), a light-emitting apparatus and manufacturing method thereof. A thin-film transistor can include an active layer and a main gate electrode spaced from the active layer, the main gate electrode can be made of conductive material, wherein, the thin-film transistor can further include an auxiliary gate electrode spaced from the active layer, the main gate electrode and the auxiliary gate electrode can be respectively located at two different sides of the active layer in the direction of the thickness of the active layer, the auxiliary gate electrode can be made of phase or phase change material, the phase or phase change material can be an insulating material when the its temperature is lower than a preset temperature threshold value, the phase or phase change material can be a conductive material when its temperature is higher than a preset temperature threshold value, the main gate electrode and the auxiliary gate electrode can be connected to each other through a conductive material.

The light-emitting apparatus can include the thin-film transistors as described above.

A thin-film transistor can be changed into a dual-gate thin-film transistor when the temperature of the light-emitting apparatus is increased, as a result, the driving voltage and the power consumption of the light-emitting apparatus can be reduced without reducing the display brightness of the light-emitting apparatus, the heat generated by the light-emitting apparatus can be effectively configured or dissipated, the stability and working life of the light-emitting apparatus can also be improved.

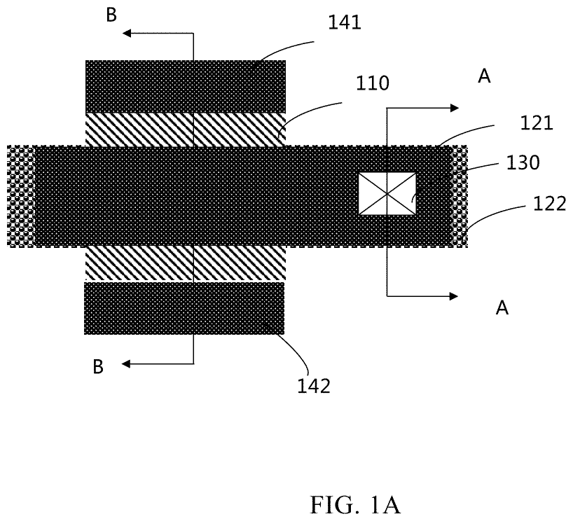

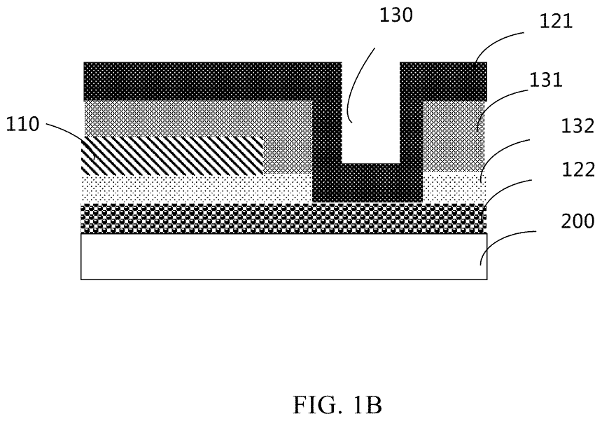

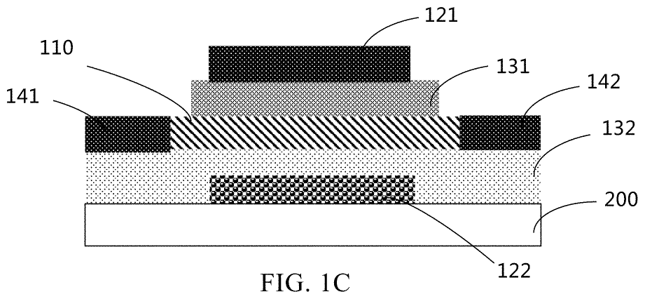

In a first aspect, a thin-film transistor can be provided, wherein FIG. 1A illustrates a top view schematic structural view, FIG. 1B illustrates a side cross-sectional view about the line A-A, and FIG. 1C illustrates a side cross-sectional view about line B-B each illustrating an exemplary schematic structural view of a thin-film transistor 10 according to some embodiments of the present disclosure.

As illustrated in FIGS. 1A, 1B, and 1C, the thin-film transistor 10, as illustrated herein can include an active layer 110 and a main gate electrode 121. In some embodiments, and as illustrated herein, the main gate electrode 121 be insulated and spaced from the active layer 110.

In some embodiments, the main gate electrode 121 can be provided utilizing a conductive material. As also illustrated herein, the thin-film transistor 10 can further include an auxiliary gate electrode 122 that can also be insulated and spaced from the active layer 110. As illustrated here, the main gate electrode 121 and the auxiliary gate electrode 122 can be respectively provided at two different or opposing sides of the active layer 110. In this embodiment, the gate electrodes are provided at top and bottom sides wherein they are separated from each other in orthogonal directions with respect to the thickness of the active layer, which can be described as residing in a plane.

In some embodiments, the auxiliary gate electrode 122 can be made of phase or phase change material. The phase or phase change material can be insulating when the temperature of the phase or phase change material is lower than a preset temperature threshold value, wherein the phase or phase change material can become conductive when the temperature of the phase or phase change material is higher than a preset temperature threshold value.

In some embodiments, the main gate electrode 121 and the auxiliary gate electrode 122 can be connected to each other through a conductive material provided therebetween.

The temperature of the auxiliary gate electrode 122 can be increased as the temperature of the thin-film transistor is increased, in this manner, when the temperature of the auxiliary gate electrode 122 reaches a preset temperature threshold value associated with a desired change between the non-conductive and conductive properties, the auxiliary gate electrode 122 can become conductive, and the auxiliary gate electrode 122 can thus be electrically connected to the main gate electrode 121 above this preset temperature threshold.

As such, the thin-film transistor can thus be changed into a dual-gate thin-film transistor from a single-gate thin-film transistor, wherein the system operates as a single-gate thin-film transistor below the preset temperature threshold value. The driving voltage of a dual-gate thin-film transistor is lower than the driving voltage of a single-gate thin-film transistor, as a result, when the thin-film transistor reaches a certain temperature, the power consumption of the thin-film transistor can be reduced.

The thin-film transistors according to embodiments of the present disclosure can then be provided in various electronic devices, heat can accumulate when the electronic device is in use, and the corresponding temperature of the thin-film transistors in electronic devices can also be gradually increased.

When the thin-film transistors according to some embodiments of the present disclosure are included in electronic devices, the heating of the electronic devices will cause the thin-film transistors to be changed from “single-gate thin-film transistors” that have relatively high driving voltages to “dual-gate thin-film transistors” that have relatively low driving voltages. As a result, the overall power consumption of an electronic device can be reduced, and the working life of an electronic device can be prolonged.

In some embodiments of the present disclosure, there is no specific requirements to the preset temperature threshold value, the preset temperature threshold value can be determined according to the temperature of the electronic device after it is in use for a certain time, and the material of the auxiliary gate electrodes 122 can be selected according to the preset temperature threshold value.

It should be noted that the preset threshold temperature value should be equal to the phase or phase change temperature of the specific phase or phase change material of the auxiliary gate electrode 122 selected.

For example, when the material of the auxiliary gate electrode 122 is pure VO₂, since the phase or phase change temperature of pure VO₂ material is 68° C., the preset threshold temperature value should be 68° C.; when the material of the auxiliary gate electrode 122 is VO₂ and germanium, since the phase or phase change temperature of VO₂ and germanium is higher than 68° C., the preset threshold temperature value should be higher than 68° C.

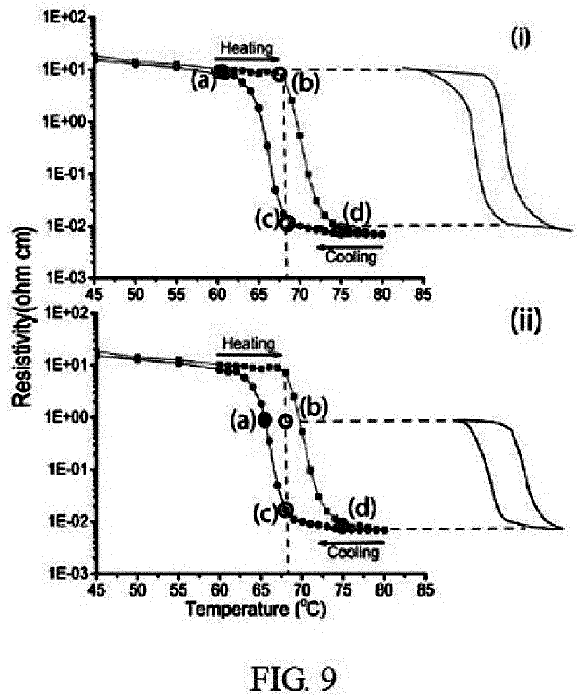

According to some embodiments of the present disclosure, the material of the auxiliary gate electrode can include vanadium oxide (VO₂). Vanadium oxide is a material having conductivity properties which vary greatly in response to temperature change, such as is illustrated in FIG. 9, which in some instances can be changed when it is changed between a liquid and a solid phase, but does not necessarily need a change in phase to realize a substantial change in conductivity, i.e. between a substantially insulative state and a substantially conductive state.

In other words, the VO₂ atomic structure changes as the temperature rises, transitioning from a crystalline structure at room temperature to a metallic structure at temperatures above 68° C. For modern electronic devices, where circuits should be able to run at 100° C., the phase transition temperature of 68° C. of the material can be lifted to more than 100° C. through the increased relative addition of metallic materials, e.g. germanium, into the vanadium oxide.

By varying the relative amounts of the metallic material within the vanadium oxide, the conductivity curve or associated phase or phase change temperature of the resulting compound can be adjusted accordingly.

In addition, the phase change process between the substantially insulative state and the semi-conductive state of the vanadium oxide compound can be very fast, for example, less than one nanosecond. Therefore, when the temperature reaches the preset temperature threshold value, it can be changed into a conductive or semi-conductive state from a substantially insulative state in a very short response time.

It should be understood that any transition process at this speed will not necessarily be recognized or observed by the human eye, and as such the display effect or light-emitting effect of the devices will not be adversely influenced.

The specific phase transition temperature can be adjusted with a material composition. For example, the phase transition temperature can be 68° C. when the material of the auxiliary gate electrode is pure VO₂, or a temperature value higher than 68° C. when the material of the auxiliary gate electrode is VO₂ and germanium.

In the embodiments of the present disclosure, there are no specific requirements with regard to the mass ratio between vanadium oxide and metallic material (e.g. germanium) in the compound forming the auxiliary gate electrodes 122. It will then be appreciated, that the mass ratio between vanadium oxide and metal can be determined according to specific desired preset temperature threshold value for a given application.

In the embodiments of the present disclosure, there are no specific requirements to the specific structure of a thin-film transistor, for example, according to some embodiments of the present disclosure, and illustrated in FIGS. 1A-1C, the thin-film transistor can include a gate insulating layer 131 and an insulating buffer layer 132.

As illustrated herein, the gate insulating layer 131 can be provided between the main gate electrode 121 and the active layer 110, while the insulating buffer layer 132 can be provided between the auxiliary gate electrode 122 and the active layer 110.

Also, as illustrated herein, a portion of the auxiliary gate electrode 122 can exceed the orthographic projection of the active layer 110 over the layer that the auxiliary gate electrode 122 is located, the main gate electrode 121 can be connected to the portion of the auxiliary gate electrode 122 that exceeds the orthographic projection of the active layer 110 through one or more vias 130, that pass through the gate insulating layer 131 and the insulating buffer layer 132 so as to allow connection of the main gate electrode 121 and the auxiliary gate electrode 122 therethrough at a distal end of the thin-film transistor.

The thin-film transistor 10 according to some embodiments of the present disclosure can further include a source electrode 141 and a drain electrode 142, the source electrode 141 and the drain electrode 142 can be provided at a common layer between the main gate electrode and the auxiliary gate electrode.

As illustrated, the source electrode 141 and the drain electrode 142 can be laterally spaced from one another on anterior sides of the active layer 110. Also, as illustrated herein, the source electrode 141 and the drain electrode 142 can be both connected to the active layer 110.

In the specific implementation illustrated in FIGS. 1A, 1B, and 1C, the source electrode 141 and the drain electrode 142 can be provided at respective opposing different sides of the active layer 110 in the direction of the length of the active layer 110 or in the direction of the width of the active layer 110.

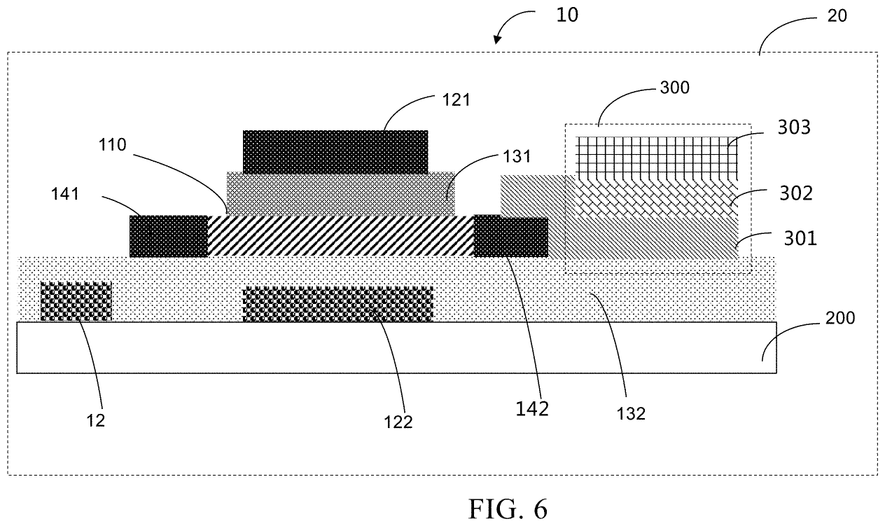

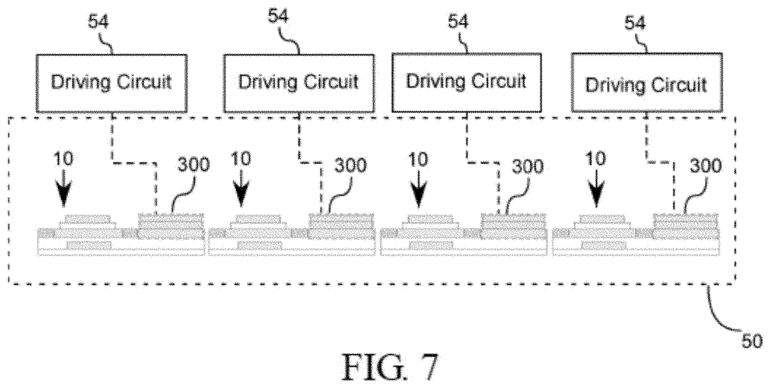

In another aspect of the present disclosure, and as illustrated in FIGS. 6 and 7, a light-emitting apparatus 50 can be provided having a plurality of pixel regions 20 in which each pixel region 20 can utilize the thin-film transistor 10 as discussed above as well as a light emitting component 300, as particularly illustrated in FIG. 6.

The light-emitting apparatus 50 can include a plurality of light-emitting components 300, and a plurality of driving circuits 54 that can be configured to drive the light-emitting components 300 to emit light.

Each light-emitting component 300 can be, for example, a light-emitting diode (LED), an organic light-emitting diode (OLED), etc. The LED or OLED can include a p-type (e.g., anode) layer 301, a light-emitting layer 302, and an n-type (e.g., cathode) layer 303.

In some such embodiments, a particular driving circuit can include, as well as be associated with each of, any one of the thin-film transistors according to abovementioned embodiments of the present disclosure.

Heat can be generated during the light-emitting process of the light-emitting components driven by the driving circuits, which heat can cause the overall temperature of the light-emitting apparatus to be increased. When the temperature of the auxiliary gate electrodes reaches a preset temperature threshold value, the material forming each auxiliary gate electrode can be changed into a conductive state.

In this manner, the thin-film transistor can be changed from a single-gate thin-film transistor to a dual-gate thin-film transistor. When the thin-film transistor changes into a dual-gate thin-film transistor, the driving voltage can be reduced such that the light-emitting apparatus will emit light normally at a significantly reduced voltage.

As a result, the power consumption of the light-emitting apparatus can be reduced. In other words, in the light-emitting apparatus according to embodiments of the present disclosure, not only the heat generated during the light-emitting process of the light-emitting apparatus can be effectively dissipated and recycled, but also the overall power consumption of the light-emitting apparatus can be reduced.

In addition, when the thin-film transistors 10 as described above are included in an electronic device, the driving voltage can be reduced, as a result, the working load of the light-emitting apparatus can be reduced, and the working life of the light-emitting apparatus can be prolonged.

In the embodiments of the present disclosure, there are no specific requirements to the specific structures and application scenarios of the light-emitting apparatus. For example, the light-emitting apparatus can be a lighting apparatus, wherein the lighting apparatus can be a display panel, or the lighting apparatus can be a backlight source in a display device.

When the light-emitting apparatus is a display panel having a plurality of pixel unit, a particular pixel region being illustrated in FIG. 6, the light-emitting apparatus can include a base substrate 200, the driving circuits can be formed over the base substrate 200, the base substrate 200 can be divided into a plurality of pixel units arranged in the form of an array, as illustrated in FIG. 7.

A light-emitting component 300 can then be provided inside each pixel unit, the driving circuits can include a plurality of gate lines, each row of pixel units can correspond to at least one gate line, the gate line can be electrically connected to the main gate electrode of corresponding thin-film transistor.

The driving circuits can drive the light-emitting components 300 to emit light of different brightness level according to different gray scales, as a result, display or functions can be realized.

As described above, when the auxiliary gate electrode of a thin-film transistor is changed into a conductive material, the driving voltage of a thin-film transistor can then be reduced and maintain operation. In the embodiments of the present disclosure, there are no specific requirements about how to reduce the driving voltage of a thin-film transistor.

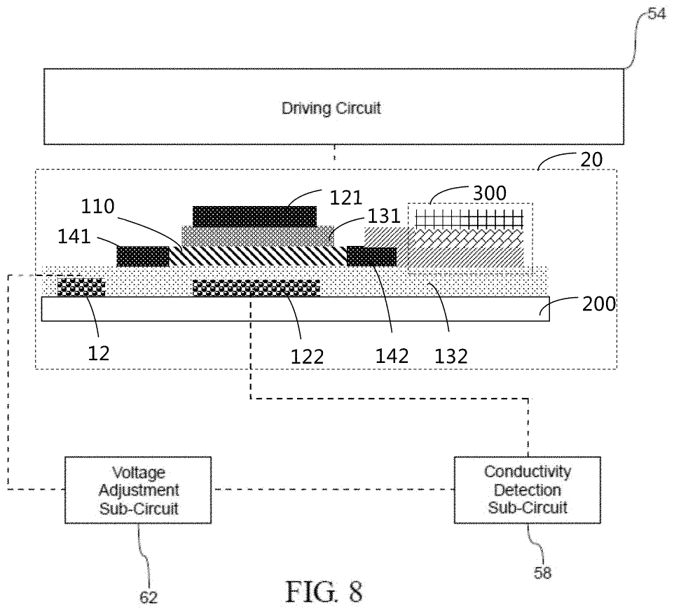

According to some embodiments of the present disclosure, and as illustrated in FIG. 8, each light-emitting apparatus can further include a conductivity detection sub-circuit and a voltage adjustment sub-circuit, the conductivity detection sub-circuit 58 which can be configured to detect whether an auxiliary gate electrode 122 is conductive and generate a trigger signal when the auxiliary gate electrode is determined to be conductive.

The voltage adjustment sub-circuit can be configured to provide a first voltage signal to a gate line when no trigger signal is received.

The voltage adjustment sub-circuit 62 can be configured to provide a second voltage signal to a gate line 12 when a trigger signal is received, the absolute value of the second voltage signal can be lower than the absolute value of the first voltage signal.

In the embodiments of the present disclosure, there are no specific requirements to the specific structure of the conductivity detection sub-circuit, for example, the conductivity detection sub-circuit can be an electric current acquisition device. When an auxiliary gate electrode is changed from an insulating auxiliary gate electrode to a conductive auxiliary gate electrode, the electric current signal in the driving circuit will change, and as such can be detected.

In accordance with some other embodiments, the temperature of the light-emitting apparatus can instead be detected and configured so as to determine whether phase or phase change has occurred to the auxiliary gate electrode 122.

In order to increase the strength of the electric current when a thin-film transistor is turned on, according to some embodiments of the present disclosure, the light-emitting apparatus 300 can further include a near-infrared light-emitting device, the auxiliary gate electrodes can be located at the side of the active layer 110 facing the base substrate 200. Accordingly, the main gate electrodes 121 can be located at the side of the active layer 110 that is opposite from the base substrate 200, wherein the material of the auxiliary gate electrodes can include vanadium oxide.

The near-infrared light-emitting device can then be configured to emit near-infrared light toward the auxiliary gate electrodes 122. Since temperature can determine if the VO₂ compound is a conductive material (metal) or an insulating material (insulator), it can also determine the frequency of light the material absorbs, the VO₂ compound material of the auxiliary gate electrodes could therefore act as a “smart window,” passing or blocking infrared light depending on the temperature outside.

When the temperature is below a preset threshold temperature value (for example, 68° C.), the VO₂ compound material of an auxiliary gate electrode 122 is an insulating material, the near-infrared light can pass through the auxiliary gate electrode 122 and reach the active layer 110.

When phase transition or phase change is occurred to the material of the auxiliary gate electrode 122 and it is changed into a conductive material, it will instead reflect near-infrared light. This being because single crystal VO₂ will change from a monoclinic phase to a tetragonal phase when crossing a temperature threshold of 68° C., wherein at temperatures which are lower than 68° C., the crystal is monoclinic and wherein, when the temperature is higher than 68° C., the crystal transforms into a tetragonal phase.

While in the tetragonal phase, the infrared permeability is low and reflective, which is due to the inherent properties of the crystal structure, resulting in infrared associated transmission and reflection based on the temperature.

Accordingly, the conductivity detection sub-circuit can be configured to detect whether an auxiliary gate electrode 122 is reflecting near-infrared light at the side of the base substrate 200 that is opposite from the auxiliary gate electrode. In this manner, when the conductivity detection sub-circuit determines near-infrared light is reflected by an auxiliary gate electrode 122, it can generate a trigger signal.

When the thin-film transistor operates as a single-gate thin-film transistor, the near-infrared light emitted can improve the strength of the electric current in a certain degree, which is beneficial for improving display brightness of the products.

It should be noted, the number of the near-infrared light-emitting devices can be one or more than one according to practical needs for a given application, the positions of the near-infrared light-emitting devices can also be provided according to practical needs for a given application; the number of the near-infrared light detection circuits can also be one or more than one according to practical needs for a given application, the positions of the near-infrared detection circuits can also be provided according to practical needs for a given application.

It should be noted, the thin-film transistor and light-emitting apparatus according to embodiments of the present disclosure can be included in any lighting systems, or products or components that have a display function such as mobile phones, tablets, televisions, monitors, wearable devices, laptops, digital frames and navigators.

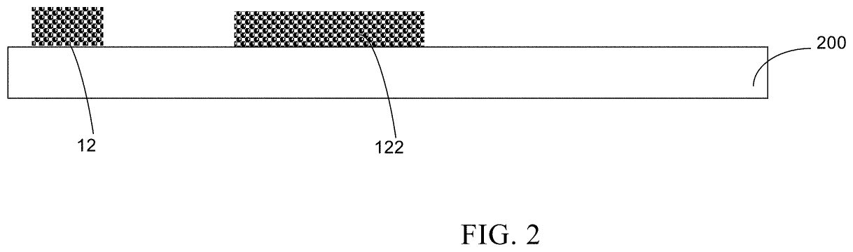

In another aspect, a manufacturing method of a light-emitting apparatus can be provided, wherein, as illustrated in FIGS. 2-6, the manufacturing method can include a number of steps, as will be discussed below.

The method can include a first step of providing a base substrate 200, such as a glass substrate 200.

The method can then include a step of forming thin-film transistors, wherein a thin-film transistor can include an active layer 110, a main gate electrode 121 that can be insulated and spaced from the active layer 110 and an auxiliary gate electrode that can be insulated and spaced from the active layer 110, the main gate electrode 121 and the auxiliary gate electrode 122 can be respectively located at two different sides of the active layer 110 in the direction of the thickness of the active layer, and the main gate electrode 121 and the auxiliary gate electrode 122 can be connected to each other through a conductive material.

It will be understood that the auxiliary gate electrode 122 can be made of a phase transition or phase change material, wherein the phase transition or phase change material can be insulating when its temperature is lower than a preset temperature threshold value, the phase transition or phase change material can be conductive when its temperature is higher than a preset temperature threshold value.

The method can then include additional steps of forming light-emitting components 300, wherein the thin-film transistors can be configured to drive the light-emitting components 300 in order to emit light.

The light-emitting apparatus according to embodiments of the present disclosure can be obtained through the abovementioned manufacturing method, the working principles and beneficial effects of the light-emitting apparatus according to embodiments of the present disclosure have been described in detail above, it will not be repeated herein.

According to some embodiments of the present disclosure, the steps of forming the thin-film transistors can include the following.

Step S1: as illustrated in FIG. 2, forming a plurality of auxiliary gate electrode patterns 122 over the substrate 200. The substrate can be, for example, a glass substrate. The auxiliary gate electrode patterns 122 can be formed, for example, by first depositing a VO₂ layer, for example using physical vapor deposition (PVD), and then patterning the VO₂ layer.

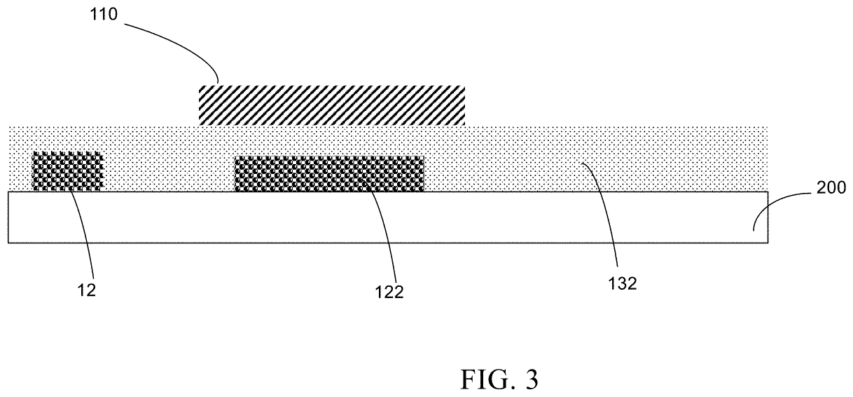

Step S2: as illustrated in FIG. 3, forming an insulating buffer layer 132. The insulating buffer layer 132 can be composed of SiOₓ, for example, and formed using plasma-enhanced chemical vapor deposition (PECVD).

A plurality of active layer (ACT) patterns 110 can be formed by sputtering of an indium gallium zinc oxide (IGZO) layer, and patterning, for example, through etching, of the IGZO layer.

Each active layer 110 can correspond to an auxiliary gate electrode 122. In some embodiments, a portion of an auxiliary gate electrode can be beyond the range of the orthographic projection of the corresponding active layer over the auxiliary gate electrode layer.

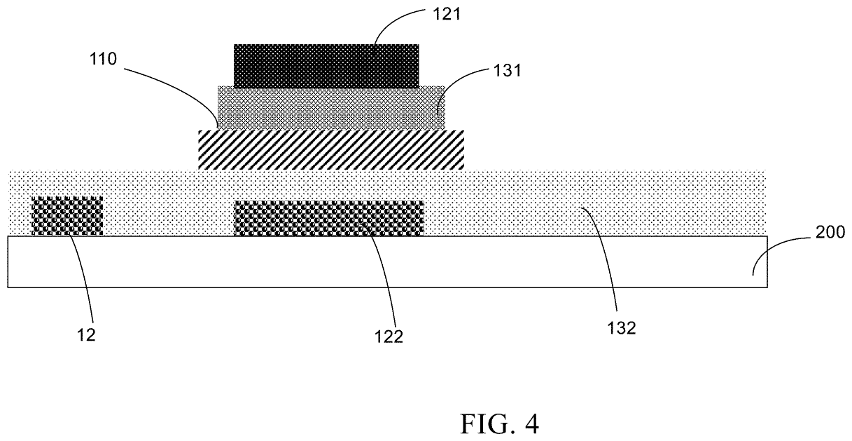

Step S3: as illustrated in FIG. 4, forming a gate insulating (GI) layer 131; forming a plurality of vias, wherein each auxiliary gate electrode can correspond to at least one via, wherein the vias can pass through the gate insulating layer and the insulating buffer layer and reach a portion of an auxiliary gate electrode that is beyond the orthographic project of corresponding active layer; forming a plurality of gate electrode patterns, as illustrated in FIG. 4, wherein the gate electrode patterns can include a plurality of main gate electrodes 121.

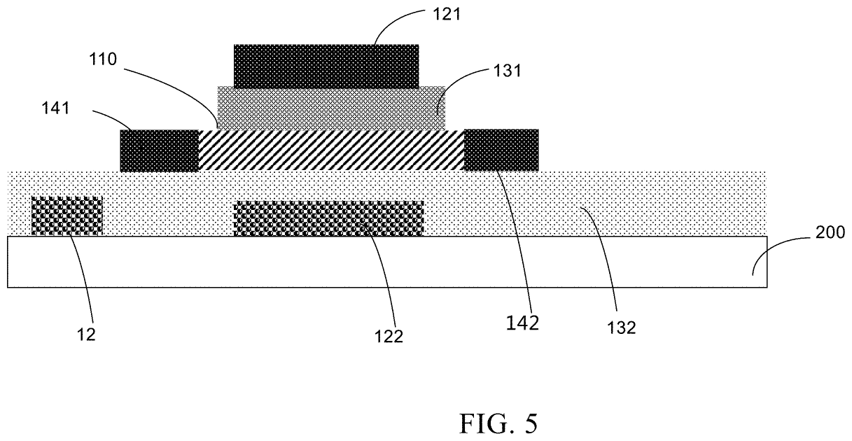

In addition, the material of a main gate electrode can be filled in the vias, such that a main gate electrode and corresponding auxiliary gate electrode can be connected. The method can then include additional steps of: Step S4: as illustrated in FIG. 5, forming a plurality of source electrode patterns 141 and a plurality of drain electrode patterns 142. The source/drain (SD) layer can be formed with, for example, copper (Cu), and the patterning of the SD layer can be realized with etching.

According to some embodiments of the present disclosure, the material of the auxiliary gate electrodes 122 can include vanadium oxide; or the material of the auxiliary gate electrodes 122 can include vanadium oxide and germanium.

In sum, a manufacturing method of a light-emitting apparatus according to some embodiments can include the steps of: providing a vanadium oxide film layer over the base substrate through a physical vapor deposition process and patterning the oxide film layer to obtain a plurality of auxiliary gate electrode patterns; providing an insulating buffer layer made of SiOₓ material through a plasma enhanced chemical vapor deposition process; providing an IGZO layer through a sputtering process, and patterning the IGZO layer to obtain a plurality of active layer patterns; providing a gate insulating layer made of SiOₓ material through a plasma enhanced chemical vapor deposition process; forming a plurality of vias which extend through the insulating buffer layer and the gate insulating layer; providing a gate metal layer through a sputtering process, and patterning the gate metal layer to obtain a plurality of main gate electrode patterns; patterning the gate insulating layer; providing a source-drain metal layer through a sputtering process; patterning the source-drain metal layer to obtain a plurality of source electrodes and a plurality of drain electrodes, and finally thin-film transistors are obtained; providing an anode layer of the light-emitting components through a sputtering process, the anode layer can be electrically connected to the drain electrodes of the thin-film transistors; providing each light-emitting functional layer through an evaporation process; providing a cathode layer through an evaporation process.

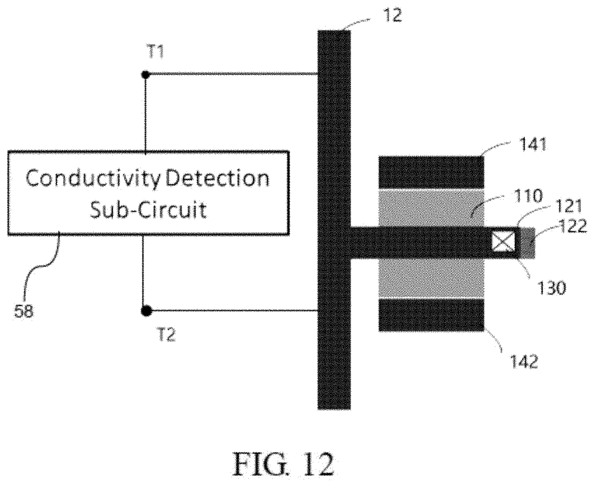

The light-emitting function layer 302 can be an electroluminescent (EL) layer, such as an organic light-emitting diode (OLED) layer. As illustrated in FIG. 12, the OLED light can be emitted through the cathode or n-type layer 303 side.

Additional steps of utilizing the light-emitting apparatus can include, for example: applying voltage to the anodes and cathodes of the light-emitting components of the organic light-emitting diodes can enable the light-emitting components to emit light, when the temperature of the light-emitting apparatus is larger than a preset threshold temperature value (for example, 68° C. for a light-emitting apparatus which auxiliary gate electrodes are made of pure VO₂ material, a temperature value that is higher than 68° C. for a light-emitting apparatus which auxiliary gate electrodes are made of both VO₂ and germanium), phase or phase change can occur to the auxiliary gate electrodes.

The foregoing has provided a detailed description on a thin-film transistor, a light-emitting apparatus and manufacturing method thereof according to some embodiments of the present disclosure. Specific examples are used herein to describe the principles and implementations of some embodiments. The description is only used to help understanding some of the possible methods and concepts. Meanwhile, those of ordinary skill in the art can change the specific implementation manners and the application scope according to the concepts of the present disclosure. The contents of this specification therefore should not be construed as limiting the disclosure.

In the foregoing method embodiments, for the sake of simplified descriptions, they are expressed as a series of action combinations. However, those of ordinary skill in the art will understand that the present disclosure is not limited by the described action sequence.

According to some other embodiments of the present disclosure, some steps can be performed in other orders, or simultaneously.

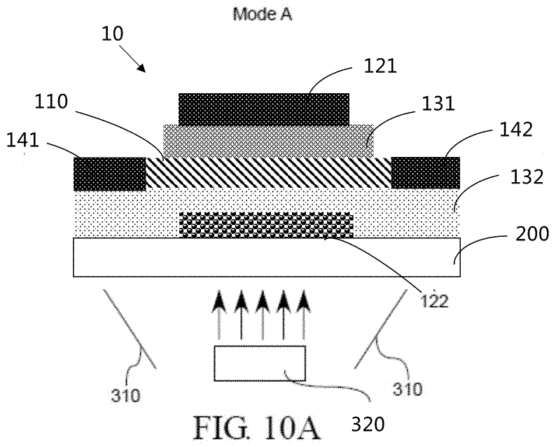

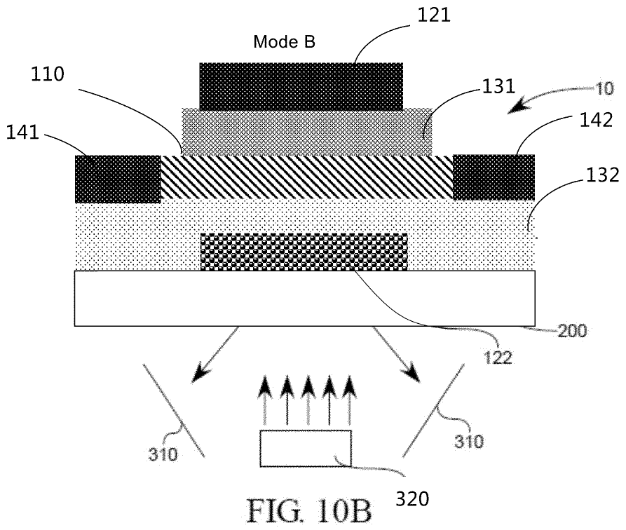

FIG. 10A illustrate a schematic diagram of a driving mechanism of the thin-film transistor according to some embodiments in a first mode, i.e., “Mode A.”

FIG. 10B illustrate a schematic diagram of a driving mechanism of the thin-film transistor according to some embodiments in a second mode, i.e., “Mode B.”

The thin-film transistors can be energy-saving transistors driving a display apparatus or a lighting apparatus.

As shown, in the top-gate TFT structure, a VO₂ layer 122, which can have a temperature-controlled phase transition, is connected to the main gate electrode 121. When the temperature of the VO₂ layer 122 is less than a specific temperature (for example, 68° C., the bulk phase-transition temperature of VO₂), the VO₂ layer 122 is an insulating state, and the TFT is a single-gate TFT, with only the main gate electrode 121 acting as the single gate.

In this mode, illustrated as “Mode A,” infrared (IR) light, such as near-IR light, emitted by an infrared light source 320 can penetrate the VO₂ layer 122 without being substantially reflected, i.e., without being detected by the infrared detector(s) 310.

The infrared light sources 320 according to some embodiments can be dedicated light sources distributed throughout the light-emitting apparatus for the plurality of pixel units 20. Yet in some other embodiments the infrared light sources 320 can be part of the light-emitting components 300.

In some embodiments, the infrared light sources 320 not only function as light sources for the infrared detectors 310 to detect whether the phrase change occurs, but also can function as heat sources to heat up the VO₂ layer 122, in a case that recycled heat from the light-emitting apparatus is insufficient to cause the desired phrase transition.

When the temperature of the VO₂ layer 122 is higher than the specific temperature, the VO₂ lattice undergoes a phase transition, and the VO₂ layer transitions from an insulator to a conductive metal layer. In this mode, illustrated as “Mode B,” the TFT becomes a dual-gate TFT, with the VO₂ layer 122 acting as the auxiliary gate.

After the phase transition, the infrared light impinging upon the VO₂ layer 122 can be reflected back, and be detected by the infrared detector(s) 310.

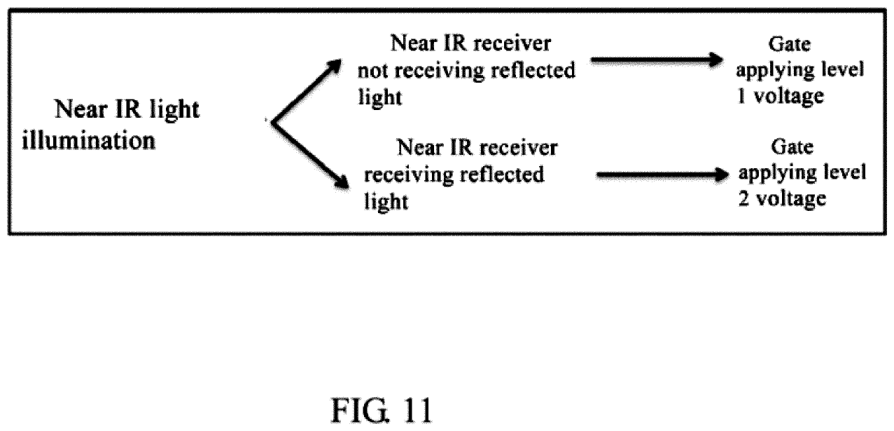

FIG. 11 is a schematic diagram illustrating an energy-saving effect of the TFT according to some embodiments.

As shown, by employing the novel energy-saving TFT driving a display and a light source, when the device is in the Mode A, a slightly higher voltage can be applied to the gate of the TFT, for example at level 1, under the same display or luminance of the light source.

During the operation of the device, the device itself and the ambient may be subject to a gradual temperature rise. When the specific temperature value is reached, the device enters Mode B. At the same time, it can be determined whether the temperature reaches the phase-transition temperature, for example by detecting the near-infrared light reflected by VO₂ layer.

Once the phase transition is detected, the applied gate voltage can be lowered, for example to level 2 that is lower that level 1. At this time, the VO₂ layer acts as the other gate, and even at the slightly lower level 2 voltage the light source can provide substantially the same brightness as Mode A, thereby achieving energy saving.

FIG. 12 is a schematic diagram illustrating an energy-saving display light source product employing the TFT according to some embodiments, employing a common conductivity detection sub-circuit 58. As illustrated in FIG. 12, the conductivity detection sub-circuit 58 can be connected to the TFT by a gate line 12.

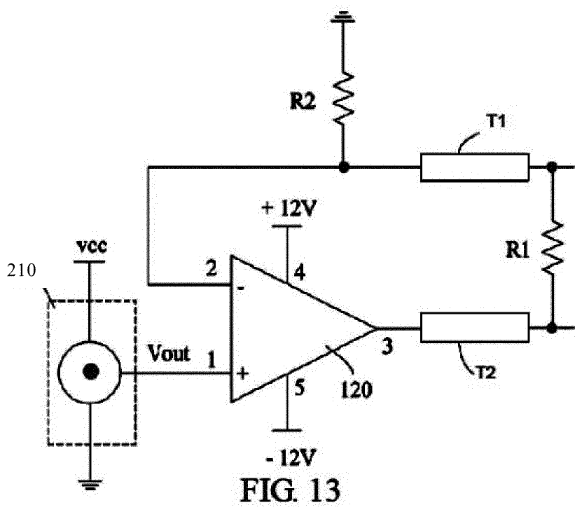

FIG. 13 is an equivalent circuit diagram, where a constant voltage module 210 is used to output a constant voltage Vₒᵤₜ.

As illustrated in FIG. 13, the circuit detects the change of the output voltage of the operational amplifier 120 through first and second detection terminals T1 and T2, which can indicate the change of the resistor R1 to be tested, for example, in this case, the resistance of the gate line 12.

R2 in this case is a voltage divider resistor.

The operational amplifier can have a non-inverting input 1, an inverting input 2, an output 3, a positive power supply input terminal 4 and a negative power supply input terminal 5.

The main gate voltage can then be adjusted according to the change of the resistance level. If the resistance is small, the applied voltage can be low accordingly.

It should be noted that since the main gate and the auxiliary gate are connected together through the overlapping holes. The auxiliary gate comprising vanadium dioxide is a non-conductive insulating layer before the phase transition, and the resistance value of the gate line 12 is Rp 1.

After the phase transition occurs, the auxiliary gate becomes a conductive metal layer. At this time, it is connected to the main gate and is overall a resistor. The resistance value at this time is Rp 2 (Rp 2<Rp 1). As such, the resistance change can be detected. The change in resistance therefore indicates the change in the conductivity of the auxiliary gate.

Therefore, the detection of the conductivity changes of the main gate and the detection auxiliary gate can employ the same principle.

Moreover, a plurality of TFTs can share a conductivity detecting circuit because when a phase change occurs, the phase transition of the VO₂ film layer is throughout the VO₂ film layer, and there is no difference between the TFTs. Therefore, a plurality of TFTs sharing a single conductive detecting circuit can be realized.

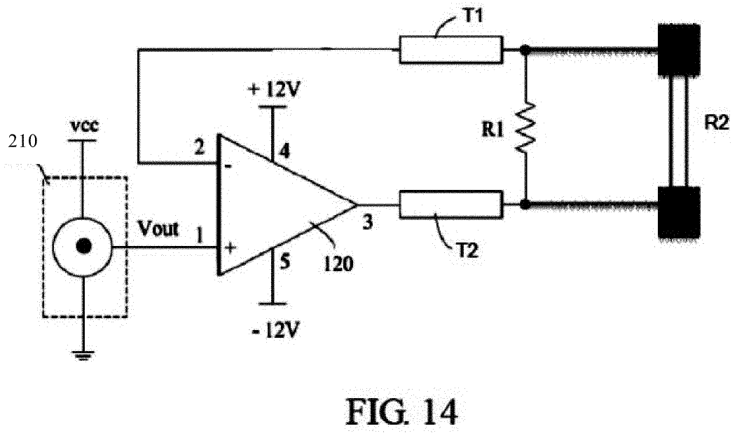

As illustrated in FIG. 14, in this structure, the resistor R1 can be provided as a fixed resistor, and the infrared photoresistor R2 can be provided as a variable resistor.

In such an arrangement, when there is no infrared reflection, the photoresistor will have a first particular fixed resistance level. When infrared rays are reflected and irradiated onto the photoresistor, the resistance level changes. In this manner, when the overall partial differential between R1 and R2 changes, the output voltage of the operational amplifier 120 changes, thereby indicating whether infrared reflection has occurred.

In response to this detection, the system can be configured to adjust the gate voltage by the control of the external circuit according to the detected differential. In this manner, the energy-saving TFT for driving the display and the light source employs the characteristics of the electronic device itself and the environment having a gradually increasing temperature to drive the phase transition of the VO₂ layer, thereby changing the working structure of the TFT, and similarly reducing the driving voltage, and thus realizing a substantial reduction in driving energy.

In this process, due to the voltage drop, the overall circuit voltage or current load is reduced, which can improve the lifetime and stability of the entire display or the light source system.

Meanwhile, the phase transition process utilizes the heat energy generated by the device, thereby recycling the otherwise wasted heat.

The phase transition temperature of VO₂ can be adjusted or controlled, for example by adding rare metal materials such as germanium, thereby meeting requirements for different phase transition temperatures of different product.

In some embodiments, the phase transition time of the VO₂ is less than 1 nanosecond. As a result, the conversion process of the device from Mode A to Mode B is not within the time range that the human eye can recognize or perceive. Therefore, it does not affect the rendering of lighting or display effects.

In some embodiments, the generation of the near infrared (NIR) light or a detection potential can be set according to product requirements, for example by setting different parameters or detection potential threshold.

When applied in a product, such as a light source, when the TFT works in Mode A, the NIR illumination can benefit the rise of the TFT current under certain conditions, thereby improving the brightness of the display or other parameters.

The novel and energy-efficient TFT according to some embodiments disclosed herein can be widely applied to energy-saving light sources, low-power display products, wearable electronic display light sources, etc.

Not only does the TFT facilitate more energy-efficient apparatuses, by utilizing the generated heat, the TFT can also facilitate expanding the lifetime and improving the stability of the apparatuses.

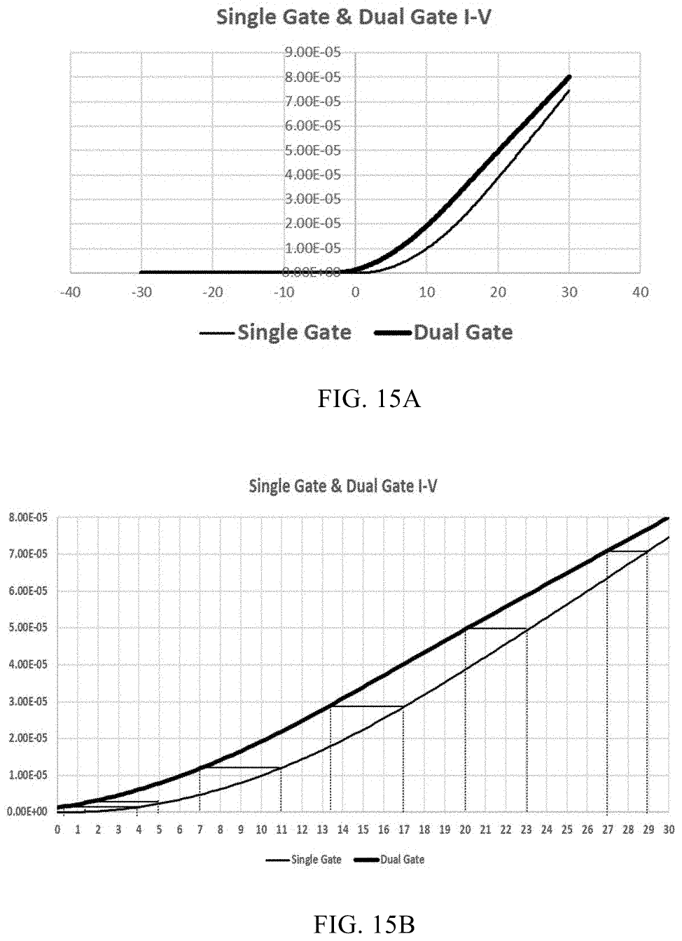

FIG. 15A is a diagram illustrating transfer characteristic curves for the single gate and the dual gate TFT according to some embodiments, as measured. As can be seen, compared with the single gate device, the dual-gate device has an earlier turn on, and an overall higher current level.

FIG. 15B is a diagram illustrating the transfer characteristic curves for the single gate and the dual gate when the gate voltage is higher than 0.

In FIG. 15B, six current levels are noted, also tabulated in the Table 1 below. The voltage which the single gate needs to provide is 4V/5V/11V/17V/23V/29V, but the same current level can be reached by the dual gate at 0.2V/1.2V/7V/13.2V/20V/26.8V.

The percentage of voltage reduction calculated in turn is 95%, 76%, 36.36%, 22.35%, 13.04%, and 7.58%. As such, based on transistor current level requirements for different display devices, under the same current output requirements, the voltage reduction in the range of 7.58%˜95% is achievable.

TABLE 1

| IDS (A) | Single gate (V) | Dual gate (V) | Voltage drop (%) |
|---|---|---|---|
| 1.41E−06 | 4 | 0.2 | 95.00 |
| 2.30E−06 | 5 | 1.2 | 76.00 |
| 1.20E−06 | 11 | 7 | 36.36 |
| 2.86E−05 | 17 | 13.2 | 22.35 |
| 4.92E−05 | 23 | 20 | 13.04 |
| 7.09E−06 | 29 | 26.8 | 7.58 |

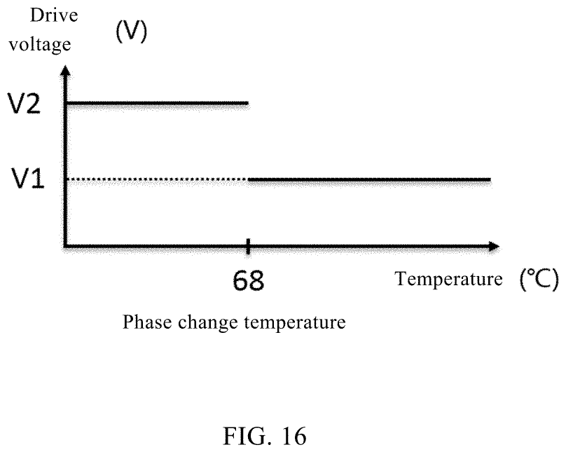

FIG. 16 is a diagram illustrating the drive voltage levels before and the after the phase transition, which as illustrated occurs at 68° C.

Those of ordinary skill in the art will understand that the embodiments described in the specification are just some of the embodiments, and the involved actions and portions are not necessarily all required to realize the functions of the various embodiments.

Various embodiments in this specification have been described in a progressive manner, where descriptions of some embodiments focus on the differences from other embodiments, and same or similar parts among the different embodiments are sometimes described together in only one embodiment.

It should also be noted that in the present disclosure, relational terms such as first and second, etc., are only used to distinguish one entity or operation from another entity or operation, and do not necessarily require or imply these entities having such an order or sequence. It does not necessarily require or imply that any such actual relationship or order exists between these entities or operations.

Moreover, the terms “include,” “including,” or any other variations thereof are intended to cover a non-exclusive inclusion such that a process, method, article, or apparatus that comprises a list of elements including not only those elements but also those that are not explicitly listed, or other elements that are inherent to such processes, methods, goods, or equipment.

In the case of no more limitation, the element defined by the sentence “includes a . . . ” does not exclude the existence of another identical element in the process, the method, the commodity, or the device including the element.

In the descriptions, with respect to device(s), terminal(s), etc., in some occurrences singular forms are used, and in some other occurrences plural forms are used in the descriptions of various embodiments. It should be noted, however, that the single or plural forms are not limiting but rather are for illustrative purposes. Unless it is expressly stated that a single device, or terminal, etc. is employed, or it is expressly stated that a plurality of devices, or terminals, etc. are employed, the device(s), terminal(s), etc. can be singular, or plural.

Based on various embodiments of the present disclosure, the disclosed apparatuses, devices, and methods can be implemented in other manners. For example, the abovementioned terminals devices are only of illustrative purposes, and other types of terminals and devices can employ the methods disclosed herein.

Dividing the terminal or device into different “portions,” “regions” “or “components” merely reflect various logical functions according to some embodiments, and actual implementations can have other divisions of “portions,” “regions,” or “components” realizing similar functions as described above, or without divisions. For example, multiple portions, regions, or components can be combined or can be integrated into another system. In addition, some features can be omitted, and some steps in the methods can be skipped.

Those of ordinary skill in the art will appreciate that the portions, or components, etc. in the devices provided by various embodiments described above can be configured in the one or more devices described above. They can also be located in one or multiple devices that is (are) different from the example embodiments described above or illustrated in the accompanying drawings. For example, the circuits, portions, or components, etc. in various embodiments described above can be integrated into one module or divided into several sub-modules.

The numbering of the various embodiments described above are only for the purpose of illustration, and do not represent preference of embodiments.

Although specific embodiments have been described above in detail, the description is merely for purposes of illustration. It should be appreciated, therefore, that many aspects described above are not intended as required or essential elements unless explicitly stated otherwise.

Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation to encompass such modifications and equivalent structures.

1. A thin-film transistor, comprising:
an active layer having a first side and a second side opposing to the first side;
a main gate electrode spaced from the active layer on the first side, and comprising a conductive material;
an auxiliary gate electrode spaced from the active layer on the second side, wherein the auxiliary gate electrode comprises a phase change material having a phase change temperature;
the auxiliary gate electrode is configured to have a transition between insulating and conductive based on a temperature of the auxiliary gate electrode; and
the main gate electrode and the auxiliary gate electrode are electrically coupled to each other when the auxiliary gate electrode is conductive.

2. The thin-film transistor of claim 1, wherein:
the auxiliary gate electrode is configured to be insulating when the temperature of the auxiliary gate electrode is lower than the phase change temperature; and
the auxiliary gate electrode is configured to be conductive when the temperature of the auxiliary gate electrode is higher than the phase change temperature.

3. The thin-film transistor according to claim 1, wherein the phase change material comprises vanadium oxide (VO₂).

4. The thin-film transistor according to claim 1, wherein auxiliary gate electrode comprises both vanadium oxide and germanium.

5. The thin-film transistor according to claim 4, further comprising:
a gate insulating layer between the main gate electrode and the active layer; and
an insulating buffer layer between the auxiliary gate electrode and the active layer.

6. The thin-film transistor according to claim 5, wherein:
a portion of the auxiliary gate electrode expands beyond a range of an orthographic projection of the active layer over a layer where the auxiliary gate electrode is located; and
the main gate electrode is connected to the portion of the auxiliary gate electrode that expands beyond the range of the orthographic projection of the active layer through one or more connection vias that pass through the gate insulating layer and the insulating buffer layer.

7. A light-emitting apparatus comprising light-emitting components, and driving circuits that are configured to drive the light-emitting components to emit light, wherein the driving circuits comprise a plurality of thin-film transistors according to claim 6.

8. The light-emitting apparatus according to claim 7, wherein the light-emitting apparatus comprises:
a base substrate; and
one or more driving circuits formed over the base substrate;
wherein the base substrate is divided into a plurality of pixel units arranged in an array, wherein a light-emitting component is provided inside each pixel unit.

9. The light-emitting apparatus according to claim 7 or 8, wherein the light-emitting apparatus further comprises:
a gate line,
wherein the main gate electrode is directly connected to the gate line.

10. The light-emitting apparatus according to claim 9, wherein the light-emitting apparatus further comprises a conductivity detection sub-circuit and a voltage adjustment sub-circuit, the conductivity detection sub-circuit is configured to detect whether the auxiliary gate electrode is conductive, then, generate a trigger signal when the auxiliary gate electrode is conductive.

11. The light-emitting apparatus according to claim 10,
wherein:
the voltage adjustment sub-circuit is configured to provide a first voltage signal to the gate line if the trigger signal is not received, and to provide a second voltage signal to the gate line when the trigger signal is received; and
an absolute value of the second voltage signal is lower than an absolute value of the first voltage signal.

12. The light-emitting apparatus according to claim 11, wherein the conductivity detection sub-circuit is an electric current acquisition device or a temperature detection device.

13. The light-emitting apparatus of claim 10, wherein the conductivity detection sub-circuit comprises:
a near-infrared light-emitting device; and
a near-infrared light detecting device, wherein
the near-infrared light-emitting device is configured to emit near-infrared light towards the auxiliary gate electrode, and
the near-infrared light detecting device is configured to detect an intensity of near-infrared light reflected by the auxiliary gate electrode, and generate the trigger signal.

14. A driving method of the light emitting apparatus according to claim 7, the method comprising:
providing a first voltage signal to the main gate electrode when the temperature of the auxiliary gate electrode is lower than the phase change temperature, or a second voltage signal to the main gate electrode when the temperature of the auxiliary gate electrode is higher than the phase change temperature;
wherein an absolute value of the second voltage is lower than an absolute value of the first voltage.

15. The driving method according to claim 14, further comprising:
detecting an intensity of near-infrared light reflected by the phase change material to thereby determine whether the phase change occurs.

16. The driving method according to claim 14, further comprising:
detecting a conductivity of the auxiliary gate electrode to thereby determine whether the phase change occurs.

17. The driving method according to claim 16, further comprising:
adjusting a voltage applied to the main gate electrode based on whether the phase change occurs.

18. The driving method according to claim 15, wherein the detecting the intensity of near-infrared light reflected by the phrase change material comprises detecting with a photoresistor.

19. The driving method according to claim 14, further comprising providing heating or cooling to change the temperature of the auxiliary gate electrode.

20. The driving method according to claim 14, further comprising inducing a phrase transition of the phase change material with heat from the light-emitting apparatus, to thereby cause the thin-film transistors to effectively change from a single-gate thin-film transistor to a dual-gate thin-film transistor, and reduce a driving voltage of the thin-film transistor and a power consumption of the light-emitting apparatus, wherein the phase transition occurs while a brightness of the light-emitting apparatus is maintained.

21. (canceled)
